(19) United States
(12) Patent Application Publication
(10) Pub. No.: US 2014/0170310 A1
(43) Pub. Date: Jun. 19, 2014

(54) COLLOIDAL LITHOGRAPHY METHODS FOR FABRICATING MICROSCOPIC AND NANOSCOPIC PARTICLE PATTERNS ON SUBSTRATE SURFACES

(71) Applicants: Li Jia, Hudson, OH (US); Sarang Pramod Bhawalkar, Akron, OH (US); Jun Qian, Zhejiang (CN)

(72) Inventors: Li Jia, Hudson, OH (US); Sarang Pramod Bhawalkar, Akron, OH (US); Jun Qian, Zhejiang (CN)

(21) Appl. No.: 13/878,287

(22) PCT Filed: Oct. 10, 2011
(86) PCT No.: PCT/US11/55604

§ 371 Date: Feb. 20, 2014

Related U.S. Application Data
(60) Provisional application No. 61/391,204, filed on Oct. 8, 2010.
(60) Provisional application No. 61/391,828, filed on Oct. 11, 2010.

(51) Int. Cl. G03F 7/00

(52) U.S. Cl. CPC G03F 7/0002
USPC 427/202

(57) ABSTRACT

A method of surface patterning by transferring particles interfacially trapped at an air-water interface to a substrate includes the steps of: (a) interfacially trapping a plurality of particles at an air-water interface; (b) providing a substrate having a polymer adhesive thereon, the polymer adhesive having a glass transition temperature that is less than 25° C. and an advancing water contact angle greater than 50; and (c) transferring the particles of step (a) to the substrate of (b) by the Langmuir-Schaefer technique.

### CROSS-REFERENCE TO RELATED APPLICATIONS

This application claims priority to International Application No. PCT/US2011/055604 filed on Oct. 10, 2011 which claims priority to U.S. Provisional Application No. 61/391,828 filed on Oct. 11, 2010 and U.S. Provisional Application No. 61/391,204 filed on Oct. 8, 2010, the contents of which are incorporated herein by reference.

### FIELD OF THE INVENTION

The present invention generally relates to lithographic methods, and, more particularly, to microlithography and nanolithography methods for fabricating microscopic and nanoscopic particle patterns on substrate surfaces. In particular, this invention relates to colloidal lithography methods particularly useful for patterning non-planar surfaces. In particular embodiments, a polymer brush adhesive layer applied to the substrate serves to secure the particle against lateral capillary forces generated when absorbing colloidal particles onto the substrate from an air-water interface.

### BACKGROUND OF THE INVENTION

The emerging frontiers of many major scientific and technological areas, including optics, imaging and sensing, and bioengineering, require fabrication of microscopic and nanoscopic patterns on nonplanar surfaces. The workhorse of surface patterning, projection photolithography, has been developed to achieve defect-free, registered, arbitrary patterns on flat surfaces to meet the needs of the microelectronics industry but is severely handicapped for nonplanar surfaces because of the necessity of focusing the beam on the plane of projection. New lithographic methods capable of patterning various nonplanar surfaces are needed to fuel the advance of the emerging scientific and technological frontiers. Contact printing and imprinting methods can cope with certain curved surfaces but appear to be restricted to those having a constant magnitude of curvature and a large radius of curvature relative to the arc length at least in one dimension. Stress-driven anisotropic buckling has also been employed to generate patterns on curved surfaces. In this case, the curvature itself is a critical parameter that governs the resulting pattern and therefore imposes a restriction to this method.

Lithographic methods utilizing patterns formed by self-assembled colloidal particles, namely, colloidal lithography, have been extensively investigated because they are cost-effective compared to conventional photolithography (especially when it comes to patterning large areas) despite their limitation of only being able to form simple patterns and highly symmetric patterns. For most practical purposes of patterned surfaces, the individual surface features in a pattern must be separated from each other by a finite distance. For colloidal lithography, this has been achieved by utilizing the interstices of hexagonal close-packed (HCP) colloidal spheres, trimming HCP arrays by shrinking or etching, and by shear-induced ordering during spin-coating.

Hexagonal non-contiguously packed (HNCP) crystals of interfacially trapped, like-charged colloidal particles have been the subject of study in the last three decades. HNCP colloidal crystals trapped at an air-water interface can be directly transferred onto solid substrates to yield HNCP and distorted HCNP patterns of those particles on the substrate. Formation of the two-dimensional crystal is primarily a consequence of minimization of the repulsive electrostatic potential of the like-charged particles confined in a finite area. Transfer of the colloidal crystals from the air-water interface can be accomplished by generating electrostatic and van der Waals attractions between the particles and the solid substrate. While the electrostatic and van der Waals attractions were expected to overcome lateral capillary force acting on the particles when a thin film of water inevitably brought onto the solid substrate in the transfer process dries, it has become apparent in the art that preservation of the pattern against the lateral capillary force in the drying stage after the initial transfer is the challenging part of the patterning process. Adhesion between a hard sphere and a hard surface is usually too weak to withstand the lateral capillary force. Thus, the present invention seeks to provide methods for improving adhesion.

A few methods have been investigated to overcome the capillary forces. In one method, the water of the air-water interface is replaced with an organic fluid, e.g., ethanol. Since the magnitude of the lateral capillary force is proportional to surface tension, switching from water to ethanol results in a more than 3-fold reduction of the lateral capillary force under otherwise identical situations. However, this tactic only allows for retention of HNCP patterns with a relatively large interparticle distance. In a second method for overcoming the capillary forces, a solvent is included in the organic fluid to swell the particles and consequently create a large area of contact between the particles and the solid substrate. However, tactics that rely on particle deformation cannot be applied to particles that are not easily deformed, and inorganic particles, which can impart a variety of useful properties in the patterned surfaces that are the topic of this disclosure, are hard and not readily deformable.

In summary, it is known that charged particles held in a pattern at an air-water interface can be transferred to flat or curved substrates, and can generally maintain their pattern, when the substrate is brought into contact with the particles at the interface. However, it is also known that lateral capillary forces can compromise the pattern when the thin film of water that is inevitably brought onto the solid substrate during the transfer step dries. As the particle pattern is transferred to the substrate there is a layer of water bridging two particles. When the water is allowed to dry, the lateral capillary forces pull the particles together and destroy or at least compromise the pattern. Because it is preferably in many instances to retain as best as possible the pattern of the particles during and after the transfer, the prior art would benefit from methods for improving the retention of particle patterns despite lateral capillary forces. Further, because inorganic particles can provide beneficial properties such as magnetism, quantum effects, plasma etch resistance and the like, the art would benefit from pattern retention methods that can be readily employed with inorganic particles, not requiring deformation of the particles to increase surface area contact between the particles and the substrate.

### SUMMARY OF THE INVENTION

This invention provides a method of surface patterning by transferring particles interfacially trapped at a air-water interface to a substrate, the method comprising the steps of: (a) interfacially trapping a plurality of particles at an air-water interface; (b) providing a substrate having a polymer adhesive thereon, the polymer adhesive having a glass transition temperature that is less than 25° C. and an advancing water contact angle greater than 50; and (c) transferring the particles of step (a) to the substrate of (b) by the Langmuir-Schaefer technique.

The polymer adhesive may be provided on the substrate by two different methods disclosed herein. In a first method, polymer brushes are provided on the substrate by either being grown directly on the substrate or by first being grown and then subsequently bound to the substrate, and the brushes serve to improve the adhesion of the particles to the substrate after transfer. In a second method, the substrate is coated with a polymer or polymer mixture to improve the adhesion of the particles to the substrate after transfer.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a model of an hexagonal noncontinguously packed (HNCP) structure;

FIG. 2 shows atomic force microscope (AFM) topographic images of polymer brush-functionalized substrates. (a) Substrate homo-31; (b) Substrate co-12;

FIG. 3 depicts the Macroscopic appearance of wafers with (a) disordered 250-nm silica particles; (b) HNCP 250-nm silica particles; and (c) HNCP 100-nm silica particles;

FIG. 4 shows scanning electron microscope (SEM) and Fourier transform (FT) images of 250-nm particles on substrate co-12 after one compression (a); after 5 compression-expansion cycles (b); and after 15 compression-expansion cycles (c), Scale bar: 1 μm;

FIGS. 5a and 5b show SEM and Fourier transform Images of 250-nm silica particle arrays with various anticipated L after being transferred onto substrates homo-31 (left) and co-12 (right): (a) L=3.0D; (b) L=2.5D; (c) L=1.5D; (d) L=1.2D; (e) L=1.1D and (f) L=1.0D, Scale Bar: 1 μm;

FIGS. 6a and 6b show SEM images and FT images of silica particles with D=100 nm (a), 250 nm (b), 370 nm (c), 500 nm (d), and 750 nm (e) after being transferred onto substrates homo-31 (left) and co-12 (right);

FIG. 7 provides a schematic view of the present method for transferring interfacial HNCP particle arrays to a substrate;

FIG. 8 shows SEM images of 247-nm particles on solid substrates aiming at the Lcalc/D ratio: 1 (a), 1.1 (b), 1.2 (c), 1.4 (d), 1.6 (e), 1.8 (f), 2.0 (g), 2.5 (h), and 3 (i), Scale Bar: 1 μm;

FIG. 9 is plot of Lexp vs Lcalc, with the diagonal line, which depicts the ideal situation of Lexp=Lcalc, providing a comparison;

FIG. 10 is a plot of bond orientational order parameter vs interparticle distance;

FIG. 11 shows (a) distorted HNCP arrays of 370-nm particles coated on a spherical mound formed by deformation of a 10-μm polystyrene particle. (b) distorted HNCP arrays of 370-nm particles coated on an irregular-shaped mound formed by deformation of a cluster of several 2.7-μm polystyrene particles. (c) top-down view of a 10-μm latex sphere covered by distorted HNCP arrays of 247-nm particles; (d) side view of a 10-μm latex sphere covered by distorted HNCP arrays of 247-nm particles, Scale Bar: 1 μm; and

FIG. 12 shows (a) an HNCP lattice of 2.7-μm latex particles deformed after 1 min in diethyl ether; (b) distorted HNCP arrays of 370-nm particles on the substrate in (a); (c) an HNCP lattice of 2.7-μm particles deformed after 3 minutes in diethyl ether; (d) distorted HNCP arrays of 370-nm particles on the substrate in (c), Scale Bar: 1 μm.

### DETAILED DESCRIPTION OF ILLUSTRATIVE EMBODIMENTS

In the present invention, ordered microscale and nanoscale particles are transferred to flat and curved substrate surfaces through colloidal lithography methods. The adhesion between the particles and the substrate surface is improved by two different methods disclosed herein. In a first method, polymer brushes are grown directly on the substrate, and the brushes serve to improve the adhesion of the particles to the substrate after transfer. In a second method, the substrate is coated with a polymer or polymer mixture to improve the adhesion of the particles to the substrate after transfer. Herein, the term polymer adhesive is to be understood as a broad term that covers both the polymer brushes bound to the substrate in the polymer brush embodiments and the polymer coated on the substrate in the coated substrate embodiments.

In accordance with the method involving the formation of polymer brushes, the polymer forming the brushes has a high water-contact angle. In particular embodiments, the advancing contact angle is greater than 70 degrees. In other embodiments, the advancing contact angle is greater than 50, in other embodiments, greater than 60, and in other embodiments, greater than 70, in other embodiments, greater than 80, in other embodiments, greater than 90, in other embodiments, greater than 100, in other embodiments, greater than 105, in other embodiment, greater than 110. In other embodiments, the advancing contact angle is less than 120, in other embodiments, less than 110, and in other embodiments, less than 105, in other embodiments, less than 100, in other embodiment, less than 90, in other embodiment, less than 80, in other embodiment, less than 70, in other embodiments, less than 60. It will be appreciated that water contact angles near and above those yielding hydrophobic properties (around 90) will be useful. Thus, in particular embodiments, the water contact angle may range from 60 to 110, in other embodiments, from 65 to 90.

The polymer forming the brushes also has a low glass-transition temperature (Tg). In particular embodiments, the polymer has a glass-transition temperature of less than 25° C. In other embodiments, Tg is less than 20° C., in other embodiments, less than 15° C., in other embodiments, less than 10° C., in other embodiments, less than 5° C. and, in yet other embodiments, less than 0° C., in other embodiments, less than −5° C., in yet other embodiments, less than −15° C., in other embodiments, less than −25° C., in other embodiments, less than −35° C., in yet other embodiments, less than −45° C., in other embodiments less than −55° C., in other embodiments, less than −65° C., in other embodiments less than −85° C., in other embodiments less than −100° C., in other embodiments less than −110° C., in other embodiments less than −120° C. In particular embodiments, the Tg of the polymer may be in the range of from −150° C. to 15° C., in other embodiments, from −150° C. to 0° C., in other embodiments, from −120 to −10° C., in other embodiments, from −100 to −20° C., and in other embodiments, from −80 to −50° C.

Although not always necessary, in particular embodiments, the polymer also has a surface charge opposite to a charge on the particles to be transferred. The surface charge can be contributed by appropriately functionalizing end groups of the polymer brushes.

Particular, non-limiting examples of suitable polymer for forming the polymer brushes (polymer adhesive) include poly(n-butylacrylate), poly(n-butylacrylate-random-N,N-diethylamino ethyl acrylate) copolymer, poly(dimethylsiloxane), poly(isobutylene) and mixtures thereof.

In accordance with the method involving the formation of polymer brushes, the substrate may be chosen from virtually any substrate on which the chosen polymer brushes can be grown. The substrate will be chosen to be one that can be appropriately modified at its surface to grow the polymer brushes thereon or attach the polymer brushes thereto. Suitable non-limiting substrates include silicon wafer, polystyrene, glass, steel, titanium, gold, aluminum, and silica.

The substrate material may be planar or non-planar.

The particles may be chosen from inorganic and organic particles. They may be spherical or non-spherical and may range in size. For microscale and nanoscale assemblies, the particles will have average dimensions ranging from 1 nanometer (nm) to 100 μm. In particular embodiments, the particles range from about 10 nm to 75 μm, in other embodiments, from 50 nm to 25 μm. In other embodiments, the particles have an average diameter of greater than 1 nm, in other embodiments, greater than 5 nm, and in other embodiments, greater than 10 nm, in other embodiments, greater than 50 nm and in other embodiments, greater than 75 nm, and in yet other embodiments, greater than 100 nm. In yet other embodiments, the particles have an average diameter of less than 200 μm, in other embodiments, less than 100 μm, and, in other embodiments, less than 50 μm, in other embodiments, less than 10 μm, and in other embodiments less than 1 micron.

The particles, whether inorganic or organic particles, have a high water-contact angle so that the particle can be stably trapped at an air-water interface for subsequent transfer. In particular embodiments, the advancing contact angle is greater than 70 degrees. In other embodiments, the advancing contact angle is greater than 50, in other embodiments, greater than 60, and in other embodiments, greater than 70, in other embodiments, greater than 80, in other embodiments, greater than 90, in other embodiments, greater than 100, in other embodiments, greater than 105, in other embodiment, greater than 110. In other embodiments, the advancing contact angle is less than 120, in other embodiments, less than 110, and in other embodiments, less than 105, in other embodiments, less than 100, in other embodiment, less than 90, in other embodiment, less than 80, in other embodiment, less than 70, in other embodiments, less than 60. It will be appreciated that water contact angles near and above those yielding hydrophobic properties (around 90) will be useful. Thus, in particular embodiments, the water contact angle may range from 60 to 110, in other embodiments, from 65 to 90.

In particular embodiments, the particles are sufficiently charged to form substantially aggregate-free self-assemblies at the air-water interface, through electrostatic repulsion. If necessary, the surface of the particles can be chemically modified to achieve a sufficient charge to form desired self-assemblies. When the particles are all of like charge, they will repel one another and spread out along the air-water interface. In non-limiting examples, the particles are charged by reacting them with chemical species having one end functionalized suitably for reacting with the surface of the particle and an opposed end that will provide the desire charge and contact angle property. In particular examples, the charged opposed end is provided by alkyl chains, tertiary butyl groups, fluoro groups or polydimethylsiloxane (PDMS) groups. In a particular embodiment, the particles form hexagonal noncontinguously packed (HNCP) structures at the air-water interface. In another particular embodiment, the particles form hexagonal close-packed (HCP) structures.

Suitable non-limiting examples of inorganic particles include silic; metals such as gold, silver, iron oxides; cadmium telluride, barium chromate, and cadmium selenide. Suitable non-limiting examples of organic particles include any polymer that can be synthesized by emulsion polymerization. Two specific examples include latex and polystyrene.

To form a patterned surface in accordance with this polymer brush method, the particles are first appropriately modified, as necessary, to achieve desired charge and water-contact angle. Thereafter, the particles are dispersed at an air-water interface. In particular embodiments, the air-water interface is provided in a bounded surface (as for example, in a Langmuir-Blodgett trough), and the available surface area can be altered to achieve a self-assembly with desired spacing between particles.

In this method, the substrate is prepared by growing polymer brushes thereon. As mentioned, the substrate and polymer(s), more particularly the monomers chosen to form the polymer brushes, are chosen so that the desired brushes can be grown on the surface of the substrate. A “graft from” or a “graft onto” method may be employed. In the “graft from” method, an appropriate initiator is bound at one end to the surface of the substrate, the initiator providing a functional end for initiating polymerization of the monomers chosen to grow the brushes. In a particular embodiment, the substrate surface is functionalized with an Atom Transfer Radical Polymerization (ATRP) initiator, and ATRP process proceeds to grow the brushes. In the “graft onto” method, the polymer brushes are formed and appropriately functionalized at one end to thereafter be bound to the surface of the substrate.

In particular embodiments, the polymer brush layer is from 10 nm to 1 μm thick. In other embodiments the polymer brush layer is less than 1 μm thick, in other embodiments, less than 750 nm, in other embodiments, less than 500 nm, in other embodiments, less than 300 nm, in other embodiments, less than 140 nm, and in other embodiments, less than 80 nm, in other embodiments, less than 50 nm, in other embodiments, less than 35 nm. The thickness can be controlled through the grafting (graft onto or graft from) process.

After the substrate is prepared with the polymer brushes, the transfer of the particles to the substrate is achieved by the Langmuir-Schaefer technique, wherein the substrate is lowered horizontally toward the air-water interface and brought into contact therewith. The particles transfer to the substrate, and the layer of water that adheres thereto is blown dry or otherwise permitted to dry. The polymer brushes adhere the particles to the surface and facilitate the retention of the self-assembly structure against the negative effects of lateral capillary forces.

In accordance with the method involving the coating of the substrate with a polymer, the polymer chosen for the coating has a high water-contact angle. In particular embodiments, the advancing contact angle is greater than 70 degrees. In other embodiments, the advancing contact angle is greater than 50, in other embodiments, greater than 60, and in other embodiments, greater than 70, in other embodiments, greater than 80, in other embodiments, greater than 90, in other embodiments, greater than 100, in other embodiments, greater than 105, in other embodiment, greater than 110. In other embodiments, the advancing contact angle is less than 120, in other embodiments, less than 110, and in other embodiments, less than 105, in other embodiments, less than 100, in other embodiment, less than 90, in other embodiment, less than 80, in other embodiment, less than 70, in other embodiments, less than 60. It will be appreciated that water contact angles near and above those yielding hydrophobic properties (around 90) will be useful. Thus, in particular embodiments, the water contact angle may range from 60 to 110, in other embodiments, from 65 to 90.

The polymer also has a low glass-transition temperature (Tg). In particular embodiments, the polymer has a glass-transition temperature of less than 25° C. In other embodiments, Tg is less than 20° C., in other embodiments, less than 15° C., in other embodiments, less than 10° C., in other embodiments, less than 5° C. and, in yet other embodiments, less than 0° C., in other embodiments, less than −5° C., in yet other embodiments, less than −15° C., in other embodiments, less than −25° C., in other embodiments, less than −35° C., in yet other embodiments, less than −45° C., in other embodiments less than −55° C., in other embodiments, less than −65° C., in other embodiments less than −85° C., in other embodiments less than −100° C., in other embodiments less than −110° C., in other embodiments less than −120° C. In particular embodiments, the Tg of the polymer may be in the range of from −150° C. to 15° C., in other embodiments, from −150° C. to 0° C., in other embodiments, from −120 to −10° C., in other embodiments, from −100 to −20° C., and in other embodiments, from −80 to −50° C.

Although not always necessary, in particular embodiments, the polymer also has a surface charge opposite to a charge on the particles to be transferred. The surface charge can be contributed by appropriately functionalizing end groups of the polymer brushes.

Particular, non-limiting examples of suitable polymers for forming the polymer adhesive include poly(n-butylacrylate), poly(n-butylacrylate-random-N,N-diethylamino ethyl acrylate) copolymer, poly(dimethylsiloxane), Poly(isobutylene) and mixtures thereof.

In accordance with the method involving coating the substrate with a polymer, the substrate may be chosen from virtually any substrate to which the polymer will adequately adhere in a coating process. It will be generally appreciated that this entails that the coating material closely match the surface energy of the substrate so that the polymer will for a stable film and not dewet from the surface. Suitable non-limiting substrates include silicon, polystyrene, glass, steel, plastic films such as acrylic films and polyvinylchloride (PVC) films, titanium, mica and wood.

The substrate material may be planar or non-planar.

The particles may be chosen from inorganic and organic particles. They may be spherical or non-spherical and may range in size. For microscale and nanoscale assemblies, the particles will have average dimensions ranging from 1 nanometer (nm) to 100 μm. In particular embodiments, the particles range from about 10 nm to 75 μm, in other embodiments, from 50 nm to 25 μm. In other embodiments, the particles have an average diameter of greater than 1 nm, in other embodiments, greater than 5 nm, and in other embodiments, greater than 10 nm, in other embodiments, greater than 50 nm and in other embodiments, greater than 75 nm, and in yet other embodiments, greater than 100 nm. In yet other embodiments, the particles have an average diameter of less than 200 μm, in other embodiments, less than 100 μm, and, in other embodiments, less than 50 μm, in other embodiments, less than 10 μm, and in other embodiments less than 1 micron.

The particles, whether inorganic or organic particles, have a high water-contact angle so that the particle can be stably trapped at an air-water interface for subsequent transfer. In particular embodiments, the advancing contact angle is greater than 70 degrees. In other embodiments, the advancing contact angle is greater than 50, in other embodiments, greater than 60, and in other embodiments, greater than 70, in other embodiments, greater than 80, in other embodiments, greater than 90, in other embodiments, greater than 100, in other embodiments, greater than 105, in other embodiment, greater than 110. In other embodiments, the advancing contact angle is less than 120, in other embodiments, less than 110, and in other embodiments, less than 105, in other embodiments, less than 100, in other embodiment, less than 90, in other embodiment, less than 80, in other embodiment, less than 70, in other embodiments, less than 60. It will be appreciated that water contact angles near and above those yielding hydrophobic properties (around 90) will be useful. Thus, in particular embodiments, the water contact angle may range from 60 to 110, in other embodiments, from 65 to 90.

In particular embodiments, the particles are sufficiently charged to form substantially aggregate-free self-assemblies at the air-water interface, through electrostatic repulsion. If necessary, the surface of the particles can be chemically modified to achieve a sufficient charge to form desired self-assemblies. When the particles are all of like charge, they will repel one another and spread out along the air-water interface. In non-limiting examples, the particles are charged by reacting them with chemical species having one end functionalized suitably for reacting with the surface of the particle and an opposed end that will provide the desire charge and contact angle property. In particular examples, the charged opposed end is provided by alkyl chains, tertiary butyl groups, fluoro groups or polydimethylsiloxane (PDMS) groups. In a particular embodiment, the particles form hexagonal noncontinguously packed (HNCP) structures at the air-water interface. In another particular embodiment, the particles form hexagonal close-packed (HCP) structures.

Suitable non-limiting examples of inorganic particles include silic; metals such as gold, silver, iron oxides; cadmium telluride, barium chromate, and cadmium selenide. Suitable non-limiting examples of organic particles include any polymer that can be synthesized by emulsion polymerization. Two specific examples include latex and polystyrene.

To form a patterned surface in accordance with this surface coating method, the particles are first appropriately modified, as necessary, to achieve desired charges and water-contact angles. Thereafter, the particles are dispersed at an air-water interface. In particular embodiments, the air-water interface is provided in a bounded surface (as for example, in a Langmuir-Blodgett trough), and the available surface area can be altered to achieve a desired self-assembly.

In addition to preparing the dispersed particles, the substrate is prepared by coating the polymer(s) thereon. As mentioned, the substrate and polymer(s) are chosen so that the polymer adheres or otherwise stably coats the surface of the substrate. Virtually any appropriate method can be employed for coating the substrate. Various methods include dip coating, spin coating, and spray coating. Dip coating has been found to be particularly useful for coating non-planar surfaces.

In particular embodiments, the polymer brush layer is from 10 nm to 1 μm thick. In other embodiments the polymer brush layer is less than 1 μm thick, in other embodiments, less than 750 nm, in other embodiments, less than 500 nm, in other embodiments, less than 300 nm, in other embodiments, less than 140 nm, and in other embodiments, less than 80 nm, in other embodiments, less than 50 nm, in other embodiments, less than 35 nm. The thickness can be controlled through the coating process.

After the substrate is coated with the polymer(s), the transfer of the particles to the substrate is achieved by the Langmuir-Schaefer technique, wherein the substrate is lowered horizontally toward the air-water interface and brought into contact therewith. The particles transfer to the substrate, and the layer of water that adheres thereto is blown dry or otherwise permitted to dry. The polymer or polymers coating the surface of the substrate adhere the particles to the surface and facilitate the retention of the self-assembly structure against the negative effects of lateral capillary forces.

### EXPERIMENTAL

### Example 1

### Novel Use of Polymer Brush in Colloidal Lithography to Overcome Lateral Capillary Force

This example is directed to the polymer brush method. In this example, interfacially trapped, submonolayer hexagonal arrays of silica particles were transferred to substrate surface to form nano- and mesoscopic surface patterning. Poly(n-butyl acrylate) and poly(n-butyl acrylate-random-N,N-diethylaminoethyl acrylate) brushes were grafted on the substrates via the “graft-from” method using Atom Transfer Radical Polymerization (ATRP). The polymer brush served as an adhesive promoter between the particles and the substrate and proved to be effective for locking the particles in the hexagonal lattice against the lateral capillary force arising from a thin layer of water attached to the surface of the substrate. Several parameters that influence preservation of the order of the particle arrays were examined. These include brush thickness, brush composition, interparticle distance, and particle diameter.

### Materials

Silica particles with diameters (D) of 100 nm, 250 nm, 500 nm and 750 nm (particle size standard deviation<10%) were purchased from Angstromsphere. p-(t-Butyl) phenethyltrichlorosilane (BPTCS, Gelest) and 2-(4-Chlorosulfonylphenyl)ethyltrichlorosilane (SPTCS, Gelest) were used as received. n-Butyl acrylate (n-BA, >99%, Aldrich) was purified by passing it through a basic alumina column before use. N,N-diethylamino ethyl acrylate (DEAEA, 95%, Aldrich) was purified by vacuum distillation. Copper (I) Bromide (98%, Aldrich) was purified according to the method of Keller and Wycoff, Keller R N, Wycoff H D., Purification of CuBr, Inorg Synth 1947; 2:1.) Ethyl-2-bromoisobutyrate (E₂Br-iB, 98%, Aldrich) and N,N,N′,N′,N″-pentamethyldiethylenetriamine (PMDETA, 99%, Aldrich) were used as received. (1l-(2-Bromo-2-methyl)propionyloxy)undecyltrichlorosilane (BMPUS) was synthesized according to a literature method, Matyjaszewski, K., et al. Macromolecules 1999, 32, 8716-8724.) Anisole (99.7%, Anhydrous, Aldrich), Toluene (99.8%, Anhydrous, Aldrich), Ethanol (Anhydrous, Aldrich), Triethylamine (99%, Aldrich) were used as received. Silicon substrates were purchased from Wafer World.

### Ellipsometry Measurements

Ellipsometry measurements were performed on a Gaertner model L116C ellipsometer with a He—Ne laser (λ=632.8 nm) and a fixed angle of incidence of 70°. For the thickness calculations, the refractive indices n=1.455 for the native silicon oxide, n=1.508 for the initiator monolayer, and n=1.466 for the polymer layer were used.

### Contact Angle Measurements

Water contact angles were measured by the sessile drop technique on a Rame-Hart goniometer (Model 100-00, Mountain Lake, N.J.) using deionized water under ambient condition. The drop size used was 10 μL. Three spots on each substrate were chosen for static contact angles. The average was calculated from two independent samples and reported as mean±standard deviation.

### Molecular Weight Determination

The molecular weights of the free polymers in solution were determined by Gel Permeation Chromatography (GPC) using three Waters HR styragel columns in tetrahydrofuran at 35° C. at a flow rate of 1 mL/min. A Wyatt DAWN EOS multiangle laser light scattering (MALLS) detector plus a Waters Model 410 differential refractometer concentration detector were used.

### Atomic Force Microscopy (AFM) Studies

The surface topology and roughness of the silicon substrates modified with the polymer brushes were characterized by AFM in the tapping mode. Briefly, samples were rinsed by THF and dried by filtered air. Multimode NanoScope 111d AFM System (Veeco Inc.) operated in air and commercial silicon nitride cantilevers (DI) with an elastic modulus of 0.56 N/m were used. Surface roughness was calculated using the imaging software Solver P47 according to the following definition:

$${R}_{q} = \sqrt{\frac{1}{N} {\sum }_{i = 1}^{N} {( {z}_{i} - {z}_{av} )}^{2}}$$

where Rq is the root-mean-square roughness, zi is the height value for a specific pixel, zav is the average of the zi values, and N is the number of pixels in the scanned area.

### Electron Microscopy and Method of Image Analysis

The particle patterns were imaged with scanning electron microscopy (SEM, JEOL-6300f). All SEM samples were sputter-coated with Au (Polaron E5100 SEM coating unit) to make the surface conductive. Fourier Transform of the SEM micrographs was performed using Fourier Transform Lab-Student Edition (FTL-SE).

### Functionalization of Silica Particles

Silica particles (0.32 g) were dried in a vacuum oven for 24 h at 100° C. prior to functionalization. The particles were dispersed in anhydrous ethanol (50 mL) in a Schlenk flask and sonicated with a Fisher Scientific sonicator for 2 h. BPTCS (0.70 mL, 2.75 mmol) and SPTCS (0.30 mL, 0.61 mmol) were added to the mixture while the particles were being sonicated. After 1 h, triethylamine (1.5 mL, 10.4 mmol) was added to the flask, and the reaction was allowed to continue for 20 h at room temperature. After the reaction was completed, the particles were washed with ethanol by four centrifugation-redispersion cycles to remove the excess silanes. The particles were then dried and stored for further use.

### Synthesis of Polymer Brushes

Silicon wafers were cut into approximately 1.8 cm×4.2 cm rectangles in order to fit into the reaction flasks for surface functionalization. They were first functionalized by the ATRP initiator BMPUS following the literature procedure.15 The procedure for synthesis of polymer brush from the same work in the literature was used after minor modifications. All operations were conducted under nitrogen protection. Typically, a solution containing PMDETA, anisole and the monomer was added to a Schlenk flask and subjected to three freeze-pump-thaw cycles. Then the solution was cannulated into another Schlenk flask containing CuBr. The mixture was stirred at 90° C. and became homogenous in ˜10 min. At this time, the homogenous solution was cannulated into a third Schlenk flask which held the BMPUS-functionalized silicon wafers to start the ATRP from the surface. The solution phase initiator Ethyl-2-bromoisobutyrate (E₂Br-iB) was added immediately to the reaction mixture with a syringe. The polymerization proceeded at 90° C. for 2 d. After the reaction, the substrate was removed and washed sequentially with dichloromethane, tetrahydrofuran and isopropanol. In order to remove any free polymer chains, the substrate was placed in a Soxhlet extractor and extracted with tetrahydrofuran for 24 h followed by sonication in tetrahydrofuran for 30 minutes. The substrate was then dried with a nitrogen jet and kept for use. The polymer produced in the solution phase was used for molecular weight measurement.

### Interfacial Particle Film Formation and Transfer

The particle film at the air-water interface was formed in a Nima Langmuir-Blodgett trough (Model 102M-A). The trough had two mechanically movable barriers, which allow the interfacial area to be adjusted from 80.5 cm2 to 11.5 cm2. Typically, a 1-3 wt % dispersion of the functionalized particles in isopropanol (20-60 μL) was spread onto the surface of deionized water at a rate of 60 μL/h using a 100 μL Hamilton syringe and a KD Scientific syringe pump (Model 780100). After the particles were allowed to equilibrate for a few minutes at room temperature, the barriers were compressed to achieve a desired area of confinement at a speed of 5 cm2/min. In order to improve the regularity of the particle arrays, compression-expansion cycles were carried out. The expansion was performed at the same speed (5 cm2/min) as the compression. Transfer of the interface particle arrays was made using the Langmuir-Schaefer technique where the substrate was lowered horizontally toward the interface and was brought into contact with the interface. This should result in complete transfer of the particles to the substrate. The residual water on the substrate was blown dry by a nitrogen jet.

### Variation of Interparticle Distance

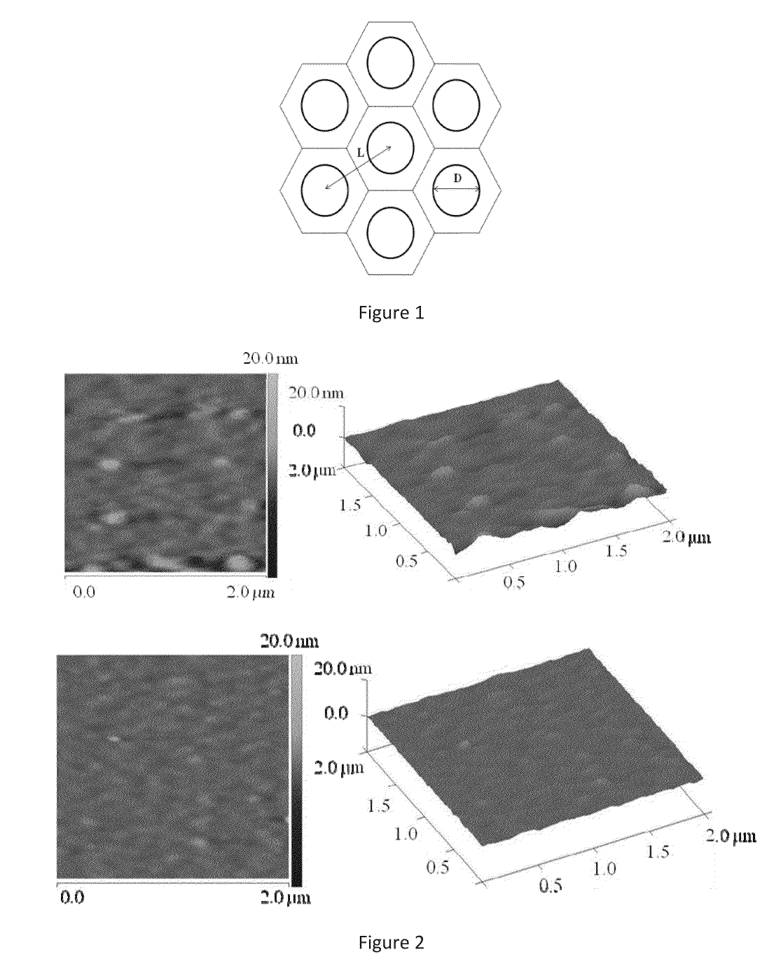

A known weight amount (M) of the particles was spread onto the air-water interface as described above. The mass of each individual particle, m, can be calculated by the formula: m=ρV=ρ4π/3(D/2)³, where ρ is the density of the particle and is specified by the supplier to be 1.8 g/cm³, V is the particle volume, and D is the particle diameter. The total number of particles at the interface, Z, therefore becomes known from Z=M/m. In an HNCP lattice, each sphere can be inscribed by a concentric hexagon as illustrated in FIG. 1. The area of each hexagon is (\sqrt{3}/2)L², and so Z(\sqrt{3}/2)L² is the total area occupied by the hexagons. This area is equal to the experimentally adjustable area between the movable barriers of the trough, A. Therefore, the interparticle distance, L, can be controlled according to L=\sqrt{2A/\sqrt{3}Z}.

### Results and Discussion

### Functionalization of Substrate

The surface of the substrate performs two functions in transferring the interfacial HNCP pattern formed by the charged particles at the air-water interface. First, it affects complete adsorption of the particles onto the substrate when the substrate is brought into contact with the particles. This is usually not a problem so long as the surface of the substrate is not easily wetted by water, or in our hands, has an advancing contact angle>70° to be safe. Second, it keeps the order of the particles intact after the particles are adsorbed on the substrate. This is the difficult part of the transfer process and requires strong adhesion between the particles and the substrate. Hydrophobic polymer adhesives are natural choices for performing the above functions. We opt in this work to use the polymer brush strategy so that the thickness and composition of the adhesive layer can be adjusted and the layer is not easily detached from the substrate.

ATRP initiated by surface-bound BMPUS was adopted to synthesize the polymer brush. 15 n-BA was used as the base monomer that provides the low glass-transition temperature (Tg) essential for a room-temperature adhesive. DEAEA was used as a minor comonomer to introduce charge as the amino units are protonated at neutral pH. Synthesis of the polymer brush and the properties of the resulting brush-covered surfaces are summarized in Table 1.

TABLE 1
Synthesis and characterization of polymer brushes

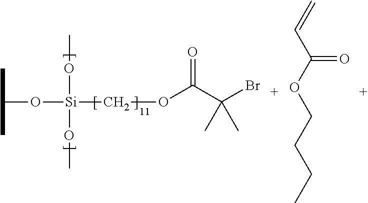

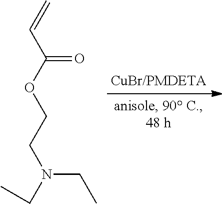

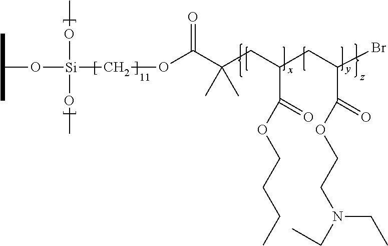

| | | | | | Brush | | Contact |
|---|---|---|---|---|---|---|---|
| | [n-BA] | [DEAEA] | Mₙ^{b} | | Thickness^{b} | R_{q} | Angle |
| Substrate | (mmol) | (mmol) | (10³ g/mol) | PDI^{b} | (nm) | (nm) | (degree) |
| homo-12 | 70.0 | — | 15 | 1.15 | 12.0 ± 2.0 | | 87 ± 3 |
| homo-31 | 139.5 | — | 31 | 1.21 | 31.0 ± 2.7 | 0.877 | 88 ± 2 |
| co-5 | 42.0 | 10.5 | 11 | 1.30 | 5.0 ± 1.1 | | 78 ± 1 |
| co-12 | 78.0 | 19.5 | 18 | 1.26 | 12.0 ± 2.6 | 0.414 | 80 ± 2 |

^{a}[CuBr] = 0.39 mmol, [PMDETA] = 0.75 mmol. Free initiator was present in all cases to obtain free polymer simultaneously, [E₂Br-iB] = 0.31 mmol.
^{b}Determined by GPC.
^{c}Determined by ellipsometry.

The thickness of the polymer brush was controlled by the concentration of the monomers. The molecular weight of the polymer brush was estimated by analyzing the free polymer in solution simultaneously produced by the “free” initiator E₂Br-iB as it has been shown that the molecular weight of the free polymer is comparable to that of the polymer brush. The trend in the brush thickness was consistent with the trend in the molecular weight. The ratio of the incorporated comonomers in the free copolymer was the same as the feed ratio (n-BA:DEAEA=80:20 in mole) according to 1H NMR analysis. By inference, the composition of the copolymer brush was likely similar to the feed ratio, too. The contact angles of all four brush-covered substrates were adequately high for the purpose of particle adsorption.

The surface topographies of randomly chosen areas of substrates homo-31 and co-12 were investigated by atomic force microscope (AFM) (FIG. 2). The root-mean-square roughness (Rq) was only a few percent of the brush thickness measured by ellipsometry in both cases (Table 1). The low surface roughness on the microscopic scale and small variation in the thickness values on the macroscopic scale confirm uniform coverage of the polymer brush on the substrate. The uniformity of the polymer brush is essential because a small defective area may trigger a cascade of imbalance of the lateral capillary force and result in the destruction of a disproportionally large fraction of the HNCP particle arrays.

### Pattern Formation and Pattern Transfer

In order for the particles to be trapped at the air-water interface and to self-assemble into the HNCP lattice, the surface of the particles must have a sufficiently high water-contact angle and be sufficiently charged. Treatment of the silica particles with a mixture of BPTCS and SPTCS in the 70:30 volume ratio (molar ratio 82:18), empirically adopted as it gave a static contact angle of 72±3° on a flat glass surface, proved satisfactory for the interfacial trapping and self-assembly. To form the interfacial particle film, the surface-modified silica particles were dispersed in isopropanol and spread onto the air-water interface in a Langmuir trough. The particle film was compressed with the movable barriers of the trough to bring the particles within the range of the electrostatic repulsion for self-assembly. The modified silicon substrate was horizontally brought into contact with the water surface and withdrawn. The substrate was then dried by a nitrogen flow.

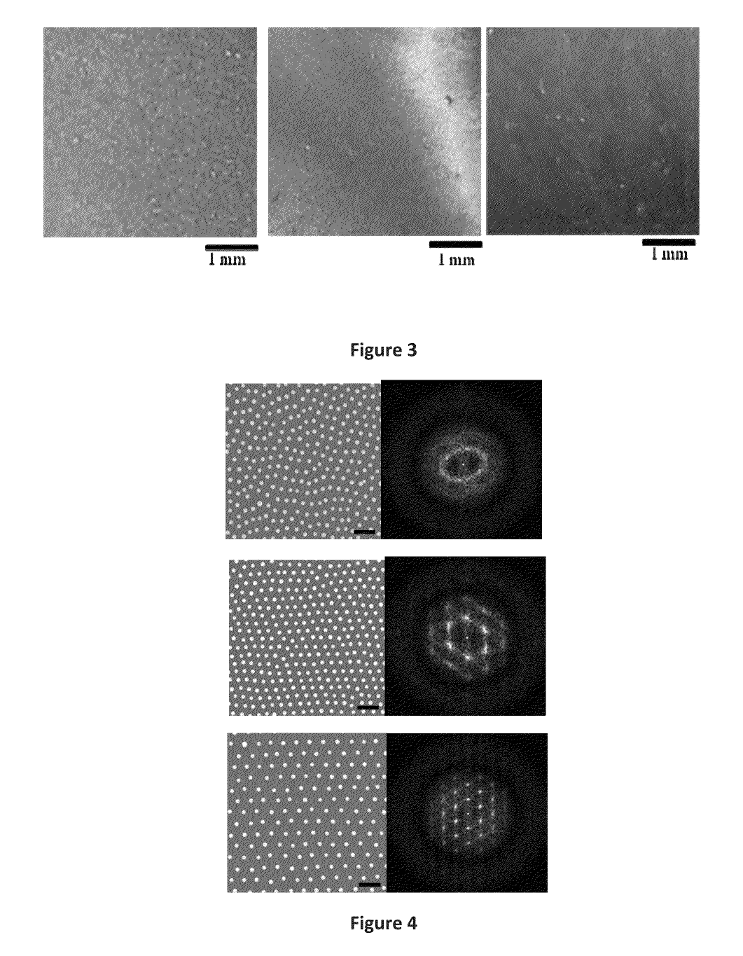

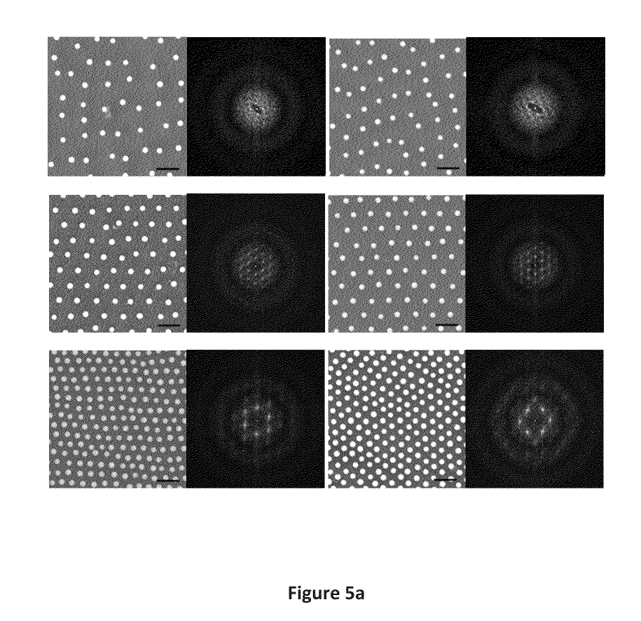

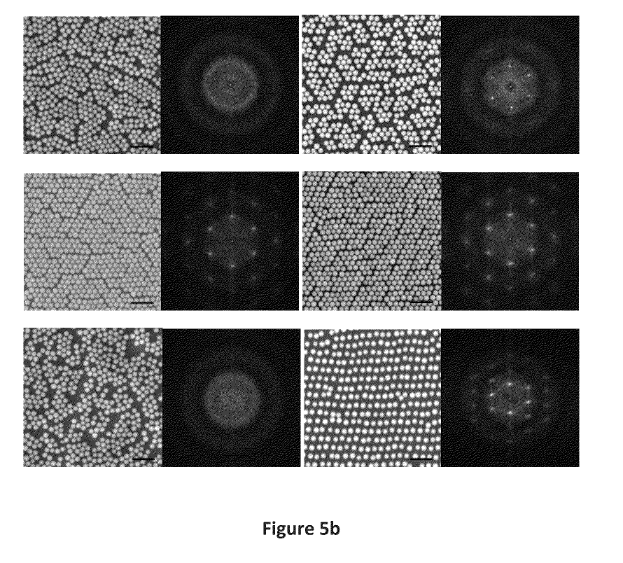

The macroscopic appearance of the wafer can usually provide the first indication about whether the order of the particle array is retained on the substrate (FIG. 3). Even a multi-grained HNCP array such as the one in FIG. 4(a) is usually sufficient to generate the angle-dependent iridescent colors, with the exception of the 100-nm particles. The HNCP 100-nm particles brought a dull blue color blended with vague luster to the substrate, indicating that scattering overtakes diffraction in color displaying. Increase in the relative intensity of the non-zeroth order diffractions and the insufficient long-range order of the pattern are likely both responsible for the change in color-displaying mode. The long-range order of the particles can be improved by subjecting the interfacial film to compression-expansion cycles. This is clearly evident from the Fourier Transformed (FT) Images (FIG. 4). The periodicities corresponding to the (10), (01), and (11) crystal lines were barely observable with one compression. After 5 compression-expansion cycles, the periodicities corresponding to the (12), (21), and (11) crystal lines appeared. After 15 cycles, the periodicities corresponding to the (13), (32), (21), (31), (23), and (12) crystal lines appeared. In this work, we routinely performed fifteen compression-expansion cycles for each experiment.

Both the thickness and the chemical composition of the polymer brush are critical for preservation of the particle pattern on the substrate. The patterns formed by the 100-nm, 250-nm, and 370-nm particles (see below for discussion on larger particles) were usually intact on substrates homo-31 and co-12 but were destroyed on substrates homo-12 and co-5. The two pairs of substrates, homo-31 vs. homo-12 and co-12 vs. co-5, bear the brushes with the same comonomer compositions but differ in the brush thickness. Therefore, a minimum brush thickness is necessary to generate adequate adhesion to lock the particles in place. This can likely be attributed to a larger contact area generated by a thicker brush and therefore greater total work of adhesion between the particles and the substrate. AFM measurements revealed that the particles were indeed partially buried in the brush. For example, the 250-nm particles were 229.9±13.8 nm (64 measurements) high on substrate homo-31 in comparison to 249.4±9.0 nm (30 measurements) on a bare silicon wafer. Since the brush thicknesses on substrates homo-12 and co-12 are approximately same, the difference in their ability to retain the particle order can be attributed to the electrostatic attraction between the positively charged brush (i.e., co-12) and the negatively charged particles.

Grafting density is obviously another critical parameter that affects the interaction between the brushes and the particles. It appears, fortunately, that the presently adopted method gives the appropriate grafting density for the polymer brushes to work as adhesive promoters. Two sets of systematic experiments were subsequently carried out to further evaluate the ability of substrates homo-31 and co-12 to lock the particles in the lattice.

Patterns with Varied Interparticle Distance

The magnitude of the lateral capillary force is strongly dependent on the interparticle distance. A comprehensive theoretical treatment of the lateral capillary force between two colloidal particles partially immersed in a water film has been given by Kralchevsky et al. The numerical solutions to the complex analytical expression show that the lateral capillary force increases sharply as the interparticle distance (L, i.e., the center-to-center distance of two particles) is reduced especially when the magnitude of L is comparable to the particle diameter (D). In a separate study, they also demonstrated using glass spheres 600 μm in diameter that the theoretical predictions were consistent with the experimentally measured values.

A series of HNCP particles with varied L were transferred in order to probe the limit of the minimum L achievable using the substrates homo-31 and co-12. The particles with the diameter of 250 nm (i.e., D=250 nm) were arbitrarily chosen for the series of experiments. FIG. 5 shows the SEM images of the transferred particles on the substrates. Well-order HNCP patterns do not form at the air-water interface at L≧3D apparently due to inadequate electrostatic repulsion but do form when L≦2.5D. Both substrates were able to retain the HNCP patterns at 2.5D≧L≧1.5D. At L=1.2D, substrate homo-31 was unable to retain the pattern, but co-12 was able to. Neither was able to retain the pattern at L=1.1D. When L=1.0D, the particles are close-packed. The experiments confirm that the HNCP patterns with a very narrow interparticle separation pose a challenge for the present surface-patterning method. Thick polymer brushes would be necessary to push the limit.

### Effects of Particle Size on Pattern Preservation

While the magnitude of the lateral capillary force is the single important variable that changes upon variation of the interparticle distance, change in the particle diameter causes changes in both the adhesion forces and the lateral capillary force. The theoretical work of Kralchevsky et al predicted a significant increase in the lateral capillary force between two particles at a fixed interparticle distance when the particle diameter increases. Practically however, when the particles with a different diameter are used to form the HNCP crystal, the achievable interparticle distance scales with the diameter. As discussed above, the increase in the interparticle distance would contribute to lowering the capillary force, opposite to the effect of particle diameter increase. From the perspective of adhesion strength, the increase in particle diameter would result in increase in the contact area between the polymer brush and the particles and in turn the increase in the overall adhesion strength. Further, if the particles migrate by rolling instead of sliding during loss of the HNCP order, the increase in particle diameter would result in increase in the torques of moments from both the adhesion force and the capillary force.

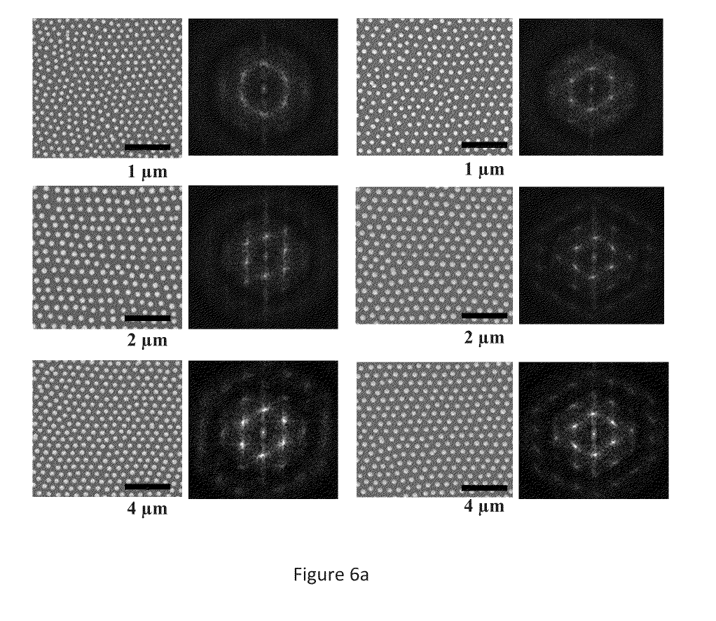

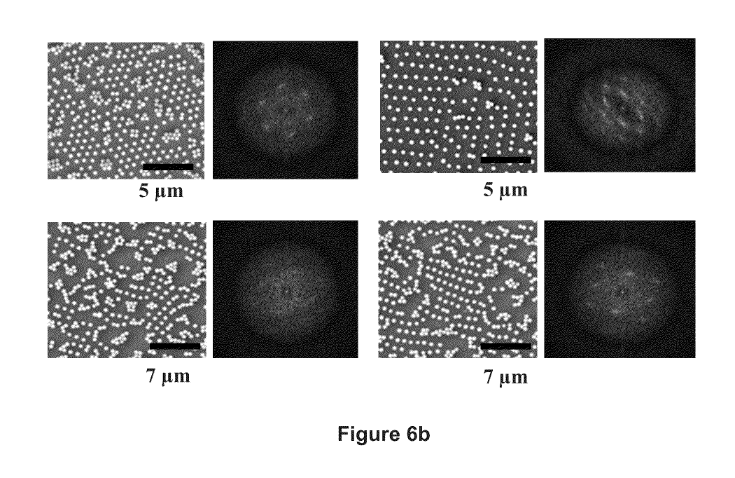

The very complex scenario upon variation of the particle size prompted us to investigate transfer of the HNCP particles of various sizes. A reasonably large variation of the particle diameter was implemented with monodisperse silica particles 100, 250, 370, 500, and 750 nm in diameter. Substrates homo-31 and co-12 were again used. The L/D ratio in the HNCP patterns was kept constant at 2. FIG. 6 shows the SEM images after the particles were transferred from the air-water interface onto the substrates. The patterns remained intact for the 100-, 250-, and 370-nm particles but were almost completely destroyed for the 750-nm particles. The 500-nm particle represented a borderline case, where the patterns were partially retained particularly when co-12 was used as the substrate. The above experiments clearly demonstrate that overall, the HNCP patterns of larger particles are more difficult to preserve than those of smaller particles.

This example demonstrates that polymer brushes can be used as adhesion promoters in a colloidal lithography process. The process is an important improvement over what has been previously developed because it does not require deformation of the particles and therefore can in principle be applied to all inorganic particles. This opens up the opportunity of using electronically, magnetically, and optically functional inorganic particles to pattern solid substrates. A minimum brush thickness is required for immobilizing the particles on the substrate against the destructive lateral capillary force. The chemical composition of the brush is also important for immobilizing the particles. Preservation of the HNCP pattern becomes increasingly challenging as the interparticle distance is reduced or the particle diameter is increased. The effect of particle diameter usually dominates over the effect of the interparticle distance.

### Example 2

### Development of Colloidal Lithography Method for Patterning Nonplanar Surfaces

This Example is directed to the polymer brush method.

In choosing the material for the adhesive layer, we took the following into consideration. First, it must have a glass transition temperature (T g) below room temperature. Further, it should possess two surface characteristics that we previously established: sufficiently high water-contact angle (advancing contact angle>70°) and surface charges opposite to the charges on the particle surface. A copolymer containing 80 mol % of n-butyl acrylate and 20 mol % of 2-(N,N-diethylamino)ethyl acrylate was synthesized to meet the above requirements. The weight average and number average molecular weights of the polymer were 33,080 and 18,690 Dalton, respectively. Tg of the bulk material was −64° C. Before the polymer adhesive was coated on the silicon substrate, the hydrophilic surface of the silicon wafer was treated with a mixture of [2-(4-chlorosulfonylphenyl)-ethyl]trichlorosilane (SPTCS) and [(P-t-butylphenyl)ethyl]trichlorosilane (BPTCS) in 1:9 mole ratio to retain the charged character of the substrate and improve the wettability of the hydrophobic polymer adhesive. The polymer adhesive in an isopropanol solution was then dip-coated on the silanized silicon wafer. A dip-coating procedure that yielded an adhesive layer 17±2 nm thick on flat silicon wafers was adopted throughout this work.

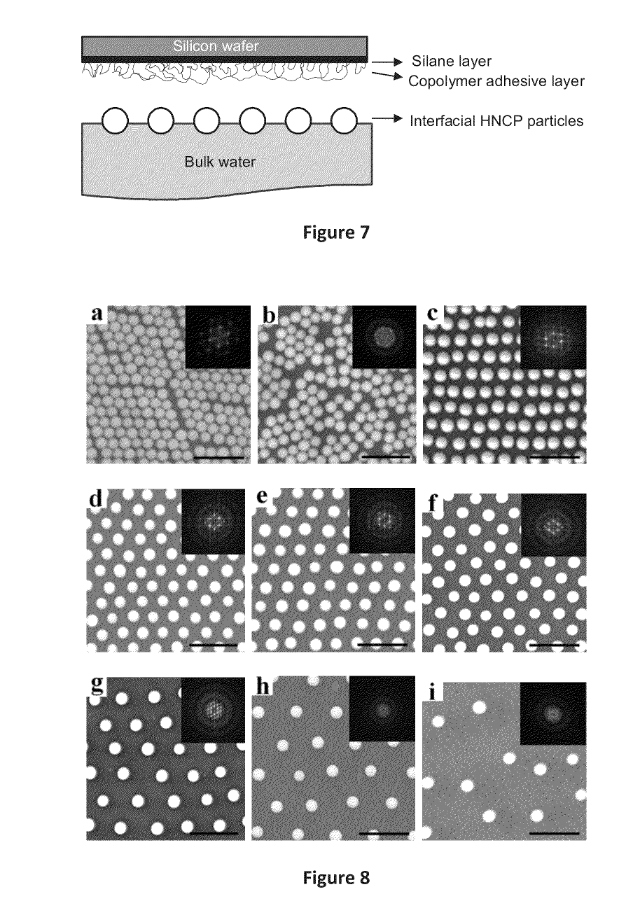

The surface of the adhesive layer had an advancing water-contact angle (THETAa) of 89±4° and a receding contact angle (THETAb) of 47±7°. Monodisperse silica particles with average diameters (D) ranging from 127 to 678 nm were used in this work. In order for the colloidal particles to be stably trapped at the air-water interface and self-assemble into the HNCP lattice, the surface of the particles must also have a sufficiently high water-contact angle and be sufficiently charged. To achieve these surface characteristics, the silica particles were treated with a mixture of SPTCS and BPTCS in 1:4 mole ratio. This empirically adopted formula proved satisfactory for interfacial trapping and self assembly. To form the HNCP pattern, the silanized silica particles were suspended in isopropanol and spread at the air-water interface in a Langmuir trough. The available area was compressed by the movable barriers of the trough. For an evenly spread particle film, the rise of surface pressure signaled the onset of the self-assembling process. The HNCP particles at the air-water interface were readily adsorbed onto the substrate when the substrate (typically 1×1 cm² in area) was brought into contact with the interface parallel to the water surface (FIG. 7). No additional post-transfer step was necessary. The very thin layer of adhesive proved sufficient to secure the HNCP lattice of the silica particles of all sizes used in this work. Since the lateral capillary force increases with the decrease in the interparticle distance, the minimal achievable interparticle distance can be expected to be a finite value, beyond which adhesion between the particles and the solid surface mediated by the adhesive layer would yield to the capillary force. The limit was probed by a set of experiments using the 247-nm particles.

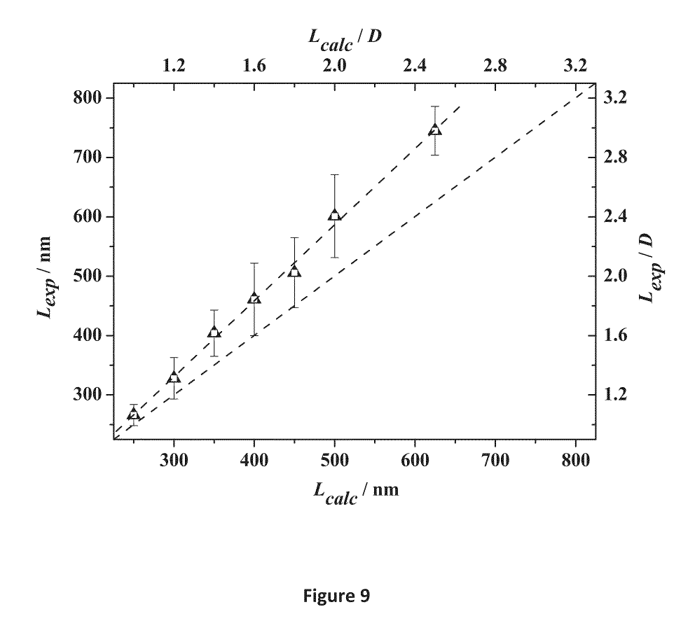

Assuming that all particles spread at the air-water interface are irreversibly trapped and given that the amount of particles spread at the air-water interface and the interfacial area are experimentally defined quantities, the interparticle distance in the HNCP lattice can be calculated. The particle films with successive calculated interparticle distances (Leale) were transferred onto the substrates and imaged by scanning electron microscopy (SEM) as shown in FIG. 8. The HNCP lattices were analyzed by Fast Fourier Transform to give the experimentally determined average interparticle distance (Lexp). A general agreement between Lexp and Lcalc is shown (FIG. 9) and therefore validates the above method for predicting the interparticle distance.

The attempt of transferring the HNCP particles with Lcalc=275 nm or 1.1D resulted in loss of order (FIG. 8b). The possibility that the loss of order is due to flocculation while the particles were at the air-water interface can be ruled out by the observation of the HCP lattice (FIG. 8a) when the interfacial film was further compressed. For Lcalc=300 nm or 1.2D, the HNCP lattice with Lexp=328±35 nm or approximately 1.3D was successfully preserved (FIG. 8c). The minimum achievable Lexp is evidently between 1.1D and 1.3D for the present colloidal lithography method. The above set of experiments also interrogated the maximum achievable Lexp, which is obviously determined by the range of the electrostatic repulsion between the same charged particles at the air-water interface. The attempt of forming the HNCP lattice with Lcalc=750 nm or 3D did not result in any ordered phase (FIG. 8i), but the HNCP lattice with Lexp=745±41 nm or −3D (Lcalc=625 nm or 2.5D) was able to form (FIG. 8h). Note that the present formulas for particle and substrate surface modification are both pragmatically adopted but not optimized. The window of achievable Lexp might expand somewhat at both ends if the critical parameters were optimal.

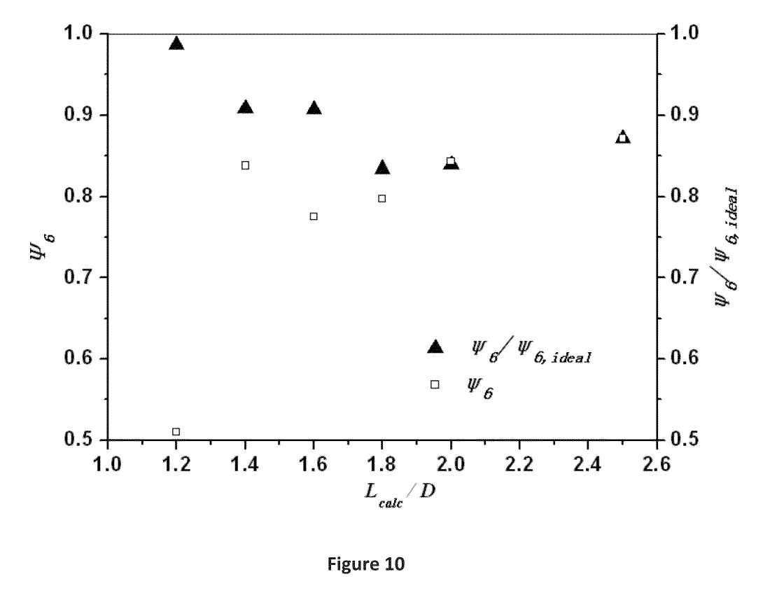

The degree of order for the particle arrays whose order was preserved (i.e., patterns with Lcalc=1.2-2.5D) was evaluated using the bond orientational order parameter:

$${Ψ}_{6} = 〈 \frac{1}{6} {\sum }_{j = 1}^{6} \vert exp ( {i6θ}_{j} ) \vert 〉$$

where θⱼ is the angle between the bond connecting a particle and its j^{th} nearest neighbor and a fixed arbitrary reference axis. The Ψ₆ value of an ideal hexagonal lattice is 1. It is immediately noticeable, as shown in FIG. 10, is that Ψ₆; of the particle array with Lcalc=1.2D (FIG. 8c) abnormally falls far from unity. This is mostly because this lattice is severely distorted from the hexagonal symmetry and is better characterized as a rhombic lattice. In fact, some extent of distortion from the perfect hexagonal symmetry is commonly observed for the particle arrays on the solid substrate presumably introduced inadvertently during the transfer process in most cases. Since Ψ₆ for the ideal rhombic lattice (Ψ_{6,}ideal) varies according to the angle a between the primitive vectors, the quotient Ψ₆/Ψ_{6,}ideal is used as a measure for the bond orientational order. To calculate Ψ_{6,}ideal=⅓|1 2 cos(3α)|, the average bond-angle value in the particle arrays was adopted as the a in the corresponding ideal rhombic lattice. According to the Ψ₆:Ψ_{6,}ideal measure, the particle arrays with the highest degree of order were obtained when the interparticle distances were small.

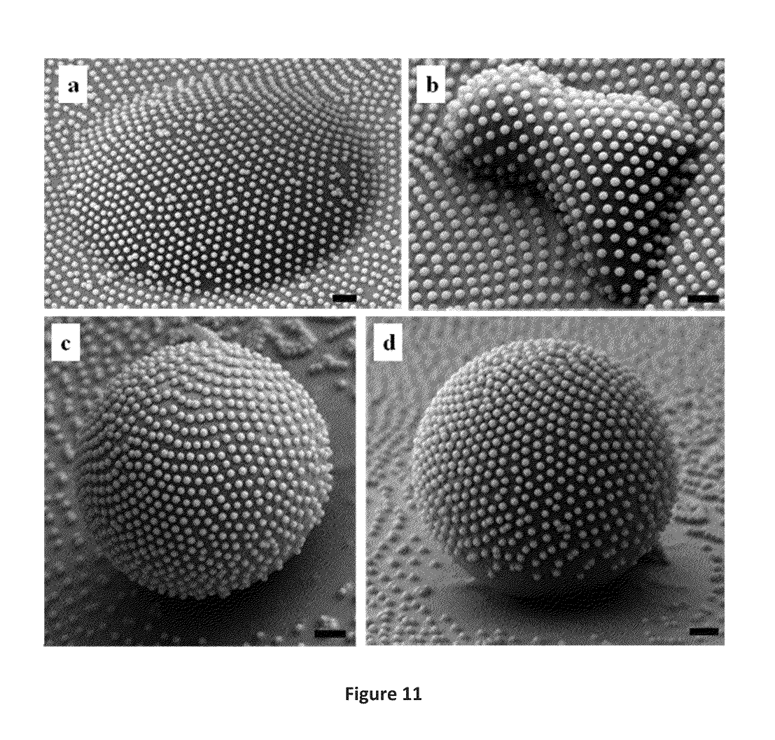

To generate the curved surfaces used in this study, polystyrene latex particles 2.7 or 9.4 μm in diameter with surface sulfate groups were randomly deposited on silicon wafers pretreated with the SPTCS/BPTCS mixture. The deposited latex particles and their small clusters were then deformed with diethyl ether to generate various curvatures on the substrate. The method developed for patterning the flat substrate was directly applied to the topographically uneven substrates. The thickness of the adhesive layer was not determined but likely in the same range as that on the flat surface. FIG. 11 shows the SEM images of several representative curved surfaces decorated with distorted HNCP arrays of silica particles. The spherical mound in FIG. 11a serves as an example of the curved surfaces, of which the magnitude of curvature is constant and the radius of curvature is large relative to the arc length. Contact printing and imprinting methods can also pattern this type of curved surface, but they likely will experience difficulties when encountering the curved surfaces such as the irregular mound in FIG. 11b, where the magnitude of the curvature is not constant. This is not a problem for the present method. The HNCP arrays at the air-water interface can readily adapt to the changing curvature and the overall topography on the substrate while maintaining the order. Note that the two dimensional HNCP lattice has to distort or stretch when they are coated on curved surfaces by virtue of the fact that the surface area of the curved surface is larger than its area of projection. The full sphere in FIG. 11c represents the type of curve, where the arch length is greater than the radius of curvature. As clearly observable from the side view in FIG. 11d, the small silica particles cover a large fraction of the large sphere well past the equatorial plane into the undercut area. The large coverage, which may be intuitively surprising, is likely attributable to the stick-slip motion of the three-phase contact line pinned on the backs of the small silica particles immediately after they are deposited on the large 10 μm sphere. The pinned contact line can conceivably drag the interfacial particle film along to cover the area that it could not reach otherwise. The situation is similar to our previous observation that dipping a flat substrate perpendicularly through the air-water interface also resulted in distorted HNCP patterns over the entire surface of the substrate. Note that when the difference between the surface areas of the mound and its projection (equal to 3πR² in the case of a full spherical mound, R is the radius of the sphere) is large as in the case of the 10 μm spherical mound, the film of the HNCP small particles may break when stretched beyond a certain point, resulting in irregular deposition of the particles in the area around the large sphere. When 3πR2 is not excessive (i.e., R is smaller), the order of the particles around the mound can be retained. At the present time, we do not know the critical 3πR² value and how it is related to other parameters such as the radius of the small particle and the interparticle distance.

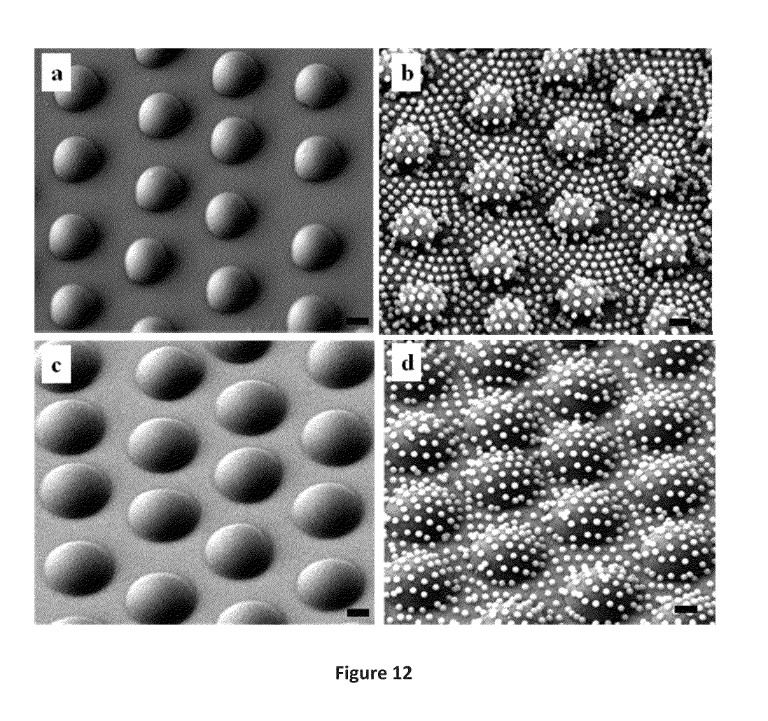

The present colloidal lithography can be repeated at two or conceivably several length scales to form hierarchical patterns. In FIG. 12, the HNCP spherical mounds were fabricated by transferring the interfacial HNCP lattice of 2.7 μm polystyrene particles onto the adhesive-coated silicon wafer followed by deformation of the polystyrene particles with diethyl ether. The substrates bearing the hexagonally arranged spherical mounds were then dip-coated again with the adhesive polymer. The interfacial HNCP arrays of small silica particles were then transferred onto the micropatterned surface to achieve the submicrometer pattern.

The present colloidal lithography method is very general and can in principle be adopted for any particles and substrates as long as an appropriate adhesive layer is applied. The appropriate adhesive layer will bind to the substrate, and will have the properties taught herein to provide the tackiness necessary to adhere the particles to the substrate and hold them against lateral capillary forces. Although the size of the substrate in the experiments has typically been 1×1 cm², there does not appear to be a fundamental reason that prevents the present method from being applied to much larger substrates. Furthermore, the patterns that it can produce should not be limited to simple hexagonal or distorted hexagonal symmetries. Nonspherical particles and binary particles can potentially be employed to expand pattern diversity and complexity. From the practical viewpoint, fabrication of optical elements with combined refractive, diffractive and subwavelength structures, for example, microlens arrays with antireflective subwavelength gratings, is an immediate application with a high probability to succeed. Other near-term applications likely would emerge from the bioengineering area, where microscopic and nanoscopic surface topographies have been shown to play important roles for cell proliferation and differentiation.

In light of the foregoing, it should be appreciated that the present invention significantly advances the art by providing a surface patterning methods that avoid the negative effects of lateral capillary forces encountered after particle transfer from an air-water interface. While particular embodiments of the invention have been disclosed in detail herein, it should be appreciated that the invention is not limited thereto or thereby inasmuch as variations on the invention herein will be readily appreciated by those of ordinary skill in the art. The scope of the invention shall be appreciated from the claims that follow.

What is claimed is:

1. A method of surface patterning by transferring particles interfacially trapped at a air-water interface to a substrate, the method comprising the steps of:
(a) interfacially trapping a plurality of particles at an air-water interface;
(b) providing a substrate having a polymer adhesive thereon, the polymer adhesive having a glass transition temperature that is less than 25° C. and an advancing water contact angle greater than 50; and
(c) transferring the particles of step (a) to the substrate of (b) by the Langmuir-Schaefer technique.

2. The method of claim 1, wherein, in step (a), the particles are arrayed in an hexagonal noncontinguously packed (HNCP) structure due to having like charges.

3. The method of claim 1, wherein the polymer adhesive is in the form of polymer brushes grown on the surface of the substrate from an initiator bound to the surface of the substrate.

4. The method of claim 1, wherein the polymer adhesive is in the form of polymer brushes formed and appropriately functionalized at one end and then bound to the surface of the substrate.

5. The method of claim 1, wherein the polymer adhesive is provided on the substrate by being coated thereon.

6. The method of claim 5, wherein the polymer adhesive is dip coated onto the substrate.

7. The method of claim 1, wherein the plurality of particles have an advancing water contact angle of greater than 50.
